(19) United States
(12) Patent Application Publication
(10) Pub. No.: US 2024/0057299 A1
(43) Pub. Date: Feb. 15, 2024

(54) THERMAL MANAGEMENT FOR ELECTRONIC COMPONENTS

(71) Applicant: Seagate Technology LLC, Fremont, CA (US)

(72) Inventors: Deepak Nayak, Pune (IN); Hemant Mohan, Pune (IN)

(21) Appl. No.: 17/885,376

(22) Filed: Aug. 10, 2022

(51) Int. Cl. H05K 7/20

(52) U.S. Cl. CPC H05K 7/20836; H05K 7/20172; H05K 7/20718

(57) ABSTRACT

A data storage system includes an enclosure, a printed circuit board positioned in the enclosure, an integrated circuit mechanically and electrically coupled to the printed circuit board, temperature sensors configured to generate temperature signals in response to measured temperatures, an air mover coupled to the enclosure and including a motor rotatable in a clockwise direction and a counterclockwise direction, and a controller configured to cause rotation of the motor in either the clockwise direction or the counterclockwise direction depending on the temperature signals.

### SUMMARY

In certain embodiments, a data storage system includes an enclosure, a printed circuit board positioned in the enclosure, an integrated circuit mechanically and electrically coupled to the printed circuit board, temperature sensors configured to generate temperature signals in response to measured temperatures, an air mover coupled to the enclosure and including a motor rotatable in a clockwise direction and a counterclockwise direction, and a controller configured to cause rotation of the motor in either the clockwise direction or the counterclockwise direction depending on the temperature signals.

In certain embodiments, a method includes measuring, using multiple temperature sensors, temperature of air at different locations within a data storage enclosure. The method further includes rotating a motor of an air mover in a clockwise direction and changing a rotation direction of the motor to a counterclockwise direction depending on the temperature of air measured at the different locations.

In certain embodiments, a system includes a controller configured to generate control signals in response to temperature signals representative of air temperatures at multiple locations within a data storage enclosure. The system further includes an integrated circuit electrically coupled to the controller and configured to drive a motor of an air mover in a first direction, then brake, and then rotate in a second direction that is opposite to the first direction.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 shows a perspective view of a data storage system, in accordance with certain embodiments of the present disclosure.

FIG. 2 shows a partial, perspective view of an enclosure, in accordance with certain embodiments of the present disclosure.

FIG. 3 shows a schematic side cutaway view of an enclosure, in accordance with certain embodiments of the present disclosure.

FIG. 4 shows a schematic top view of the enclosure of FIG. 3, in accordance with certain embodiments of the present disclosure.

FIGS. 5-7 show schematic top views of the enclosure of FIG. 3 partitioned into different sections and with different air flow configurations, in accordance with certain embodiments of the present disclosure.

FIG. 8 shows an example circuit for controlling operating modes of an air mover, in accordance with certain embodiments of the present disclosure.

FIG. 9 shows a perspective view of an enclosure with a heat chimney, in accordance with certain embodiments of the present disclosure.

FIG. 10 shows a schematic of a computing device, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope the appended claims.

### DETAILED DESCRIPTION

Data storage systems are used to store and/or process vast amounts of data. It can be challenging to keep the systems within a desired temperature range because of the amount of heat the systems typically generate during operation. Data storage systems can include cooling devices such as air movers (e.g., fans, blowers) that assist with maintaining the systems within the desired temperature range. However, by default, the air movers are not actively controlled. For example, the air movers may only operate at one speed (e.g., a single rotational speed or rpm) and in only one direction (e.g., clockwise rotation) regardless of how the air movers are affecting the internal environment of the data storage system.

Certain embodiments of the present disclosure are accordingly directed to systems, methods, and devices that utilize active control of air movers. In particular, the air movers can be actively controlled based on sensor signals such as those generated by temperature sensors, flow sensors, and/or pressure sensors. For example, air movers can be controlled such that the cooler air detected by temperature sensors is used effectively to cool electronic components within the data storage system. Put another way, using various temperature sensors and air movers, cool air can be detected and moved to locations where the cool air can be used to lower the temperature of the air and electronic components.

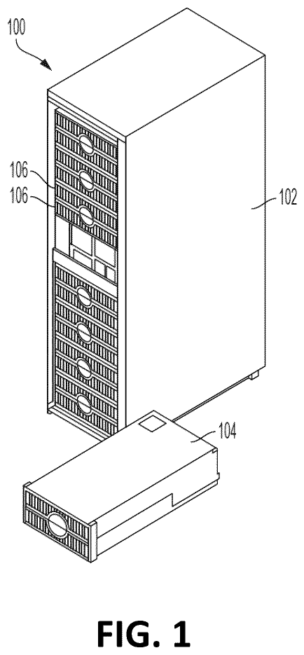

FIG. 1 shows a data storage system 100 including a rack 102 (e.g., a cabinet) with a plurality of enclosures 104. Each enclosure 104 can include multiple drawers or storage levels 106 that house data storage devices and/or data processing devices (e.g., data processing units such as graphics processing units) installed within the drawers or storage levels 106. Each enclosure 104 itself can be arranged in a drawer-like fashion to slide into and out of the rack 102, although the enclosures 104 are not necessarily arranged as such.

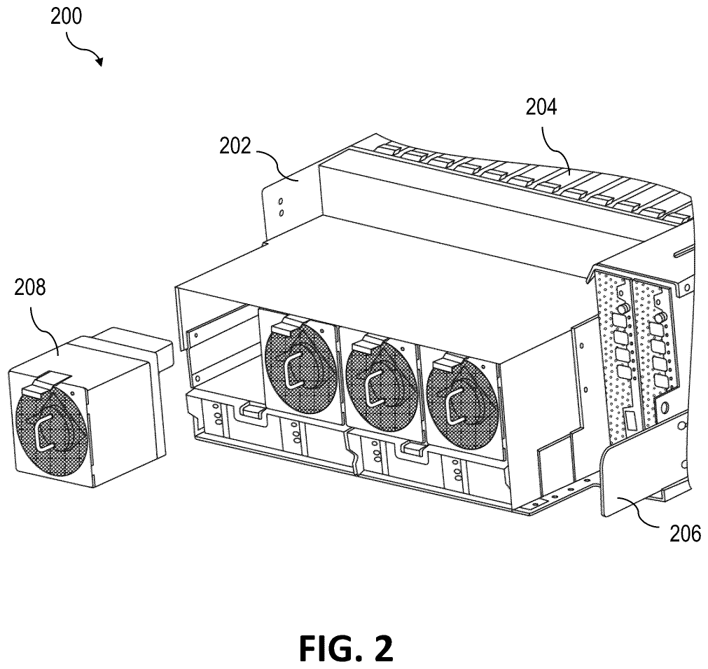

FIG. 2 shows a perspective view of a backend of an enclosure 200, which can be utilized in a data storage system such as the data storage system 100 of FIG. 1. For example, a rack such as the rack 102 in FIG. 1 can include multiple individual enclosures such as the enclosure 200.

The enclosure 200 includes a chassis 202 with various walls (e.g., side walls, bottom wall, top wall) that house data storage devices 204 (e.g., hard disk drives, solid state drives), power electronics (e.g., power supplies, batteries), data processing electronics (e.g., processor integrated circuits such as graphic processing units), and controller electronics (e.g., controller integrated circuits), among other components for assisting with processing and storing data. The enclosure 200 may include slides 206 coupled to the chassis 202 that enable the enclosure 200 to move into and out of a rack.

Air movers 208 (e.g., fans, blowers) can be positioned at different parts of the enclosure 200. In the example shown in FIG. 2, the enclosure 200 includes four air movers 208 positioned at the backend of the enclosure 200. As described in more detail below, the air movers 206 can be controlled to pull air from the frontend of the enclosure 200 to the backend and out of the enclosure 200, or vice versa. In addition, the enclosure 200 can include air movers positioned at other locations throughout the enclosure 200.

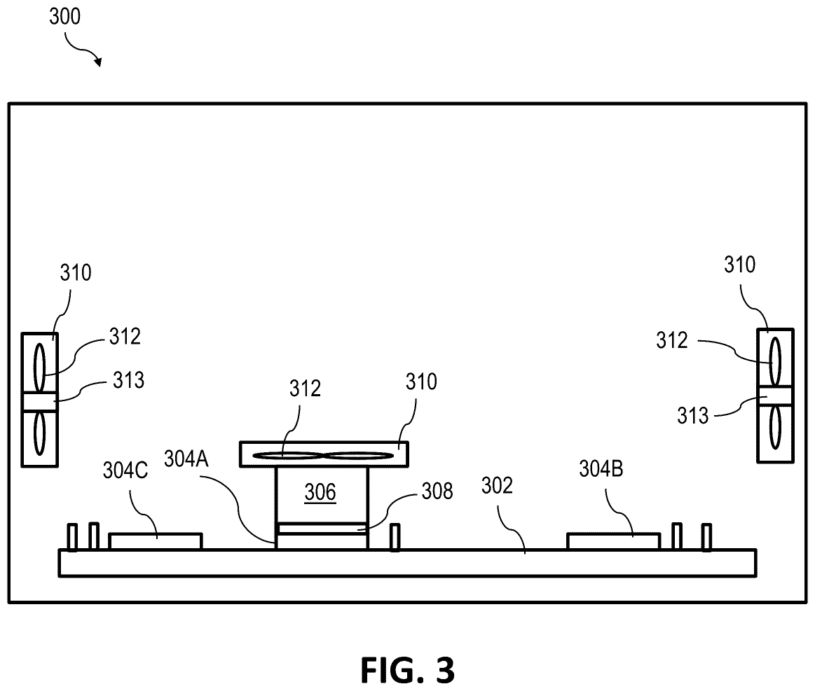

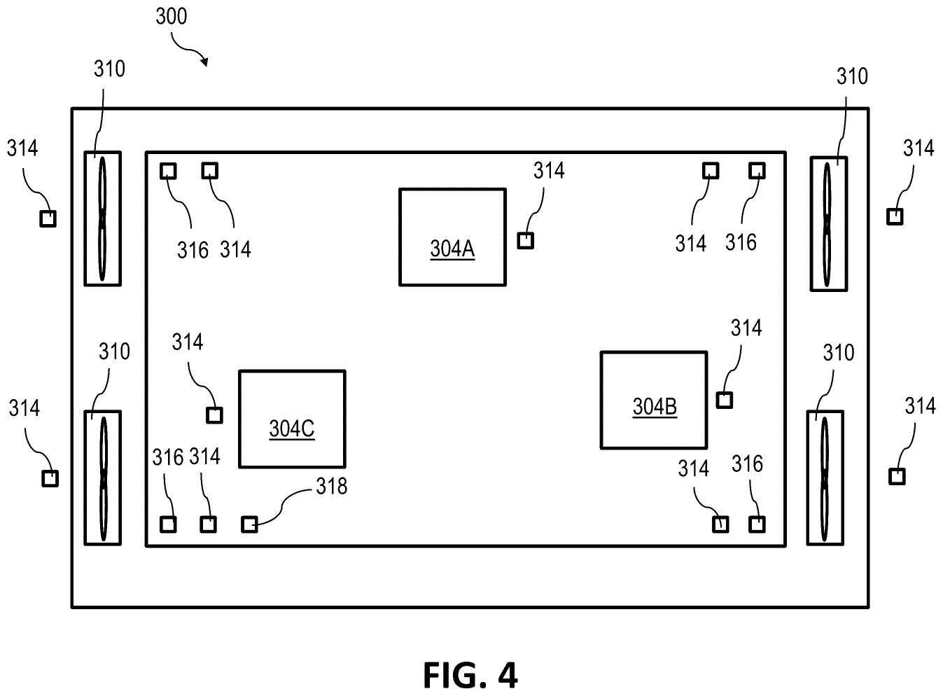

FIGS. 3-7 show various schematics of an enclosure 300, which can be utilized in a data storage system such as the data storage system 100 of FIG. 1. For simplicity of explanation, components such as mass data storage devices and power supply units are not shown in the schematics shown in FIGS. 4-7.

The enclosure 300 includes a printed circuit board 302 positioned within the enclosure 300. Various electronic components 304A-C are mechanically and electrically coupled to the printed circuit board 302. One of the electronic components 304A can be a central processing unit (CPU) or graphical processing unit (GPU) integrated circuit, another one of the electronic components 304B can be a controller integrated circuit (e.g., an application-specific integrated circuit), and the other electronic component 304C can be a data processing integrated circuit (e.g., a field-programmable gate array). Of course, other types of electronic components can be used in the enclosure 300 and additional electronic components can used other than the three electronic components 304A-C shown.

When operating, the electronic components 304A-C generate heat which increases the temperature of the interior of the enclosure 300 as well as the other components positioned in the enclosure 300. The heat can negatively affect the performance of the electronic components 304A-C and other components in the enclosure 300.

To help cool the various components, heat sinks 306 can be mechanically and thermally coupled to the electronic components 304A-C. For simplicity, only one of the electronic components 304A is coupled to the heat sink 306. The heat sink 306 can include a base that is coupled to the electronic component 304A and fins that extend from the base. In certain embodiments, a thermal interface material 308 is positioned directly between the base of the heat sink 306 and the electronic component 304A and helps conduct heat. The thermal interface material 308 can be a paste, gel, or other material that allows heat to pass from the electronic component 304A to the heat sink 306. The heat sink 306 can comprise a thermally conductive material such as aluminum or copper.

To also help cool the various components, the enclosure 300 can include air movers 310. In certain embodiments, the air movers 310 are fan modules that include impellers or blades 312 (hereinafter, collectively, “blades 312”) that rotate around a rotational axis that cause air to flow over the components positioned in the enclosure 300. For example, the air movers 310 include a motor 313 that rotates so that the blades 312 rotate. In certain embodiments, the air movers 310 are axial fans or centrifugal fans, which are sometimes called blowers.

In certain embodiments, the motors 313 of the air movers 310 can be selectively rotated to push or pull air (e.g., selectively rotated clockwise or counterclockwise). The air cools the components via convection. For example, the air movers 310 can draw air from a front end of the enclosure 300 towards the back end of the enclosure 300 and then move the air out of the enclosure 300.

In the example of FIG. 3, one of the air movers 310 is coupled to the heat sink 306. Heat generated by the electronic component 304A is passed from the electronic component 304A to the thermal interface material 308 to the heat sink 308, which is cooled by air directed towards (or drawn away) by the air mover 310.

As best seen in FIG. 4, various sensors are positioned throughout the interior of the enclosure 300 and exterior of the enclosure 300. For example, temperature sensors 314 (e.g., thermocouples, thermistors, temperature sensing integrated circuits) can be positioned adjacent each of the electronic components 304A-C such that the temperature sensors 314 can detect the temperature of the air near the respective electronic components 304A-C. In certain embodiments, the temperature sensors 314 are electrically and mechanically coupled to the printed circuit board 302 (e.g., soldered to vias or bond pads of the printed circuit board 302).

Additional temperature sensors 314 can be positioned in the enclosure 300 near each of the air movers 310 such that the temperature sensors 314 can detect the temperature of the air near the air movers 314. Temperature sensors can be positioned at other locations of the enclosure 300 too. Further, temperature sensors 314 can be positioned outside the enclosure 300 such that the temperature of the air exterior to the enclosure 300 can be detected.

In addition to temperature sensors, other sensors can be positioned throughout the enclosure 300. For example, flow sensors 316 can be positioned near one or more of the air movers 310 such that the air flow (e.g., volume of air flowing per minute) near the air movers 310 can be detected. Other sensors such as air pressure sensors 318 can be incorporated into the enclosure 300.

The output signals of the various sensors can be inputted to a central controller. For example, the electronic component 304B can be the central controller that comprises a controller integrated circuit that is arranged to receive the output signals of sensors and that is programmed to actively control the air movers 310 in response to the sensor signals.

In certain embodiments, the air movers 310 are controlled by the central controller 304B such that the cooler air within the enclosure 300 is used effectively. For example, if the temperature sensors 314 detect an area with air that is cooler than other parts of the enclosure 300, the air movers 310 can be controlled such that the cooler air is used to cool one or more of the electronic components 304A-C that are located in regions with hot air, which may be affecting performance of the given electronic components 304A-C.

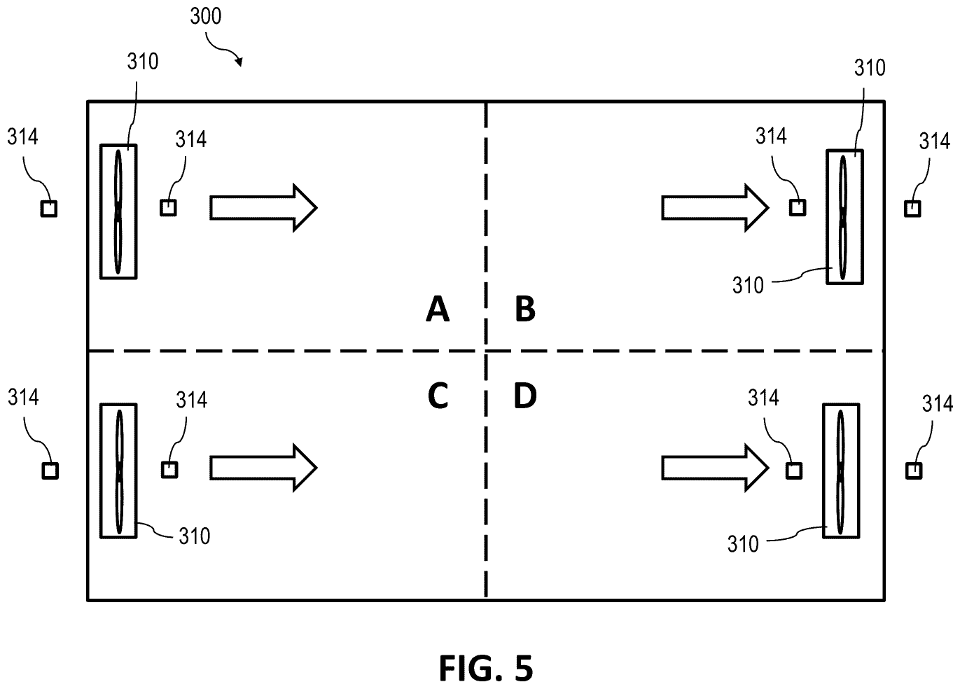

FIGS. 5-7 show simplified schematics of the enclosure 300 where most components shown in the previous figures have been removed for purposes of explaining how the air movers 310 can be actively managed to control air flow in the enclosure 300. The features described with respect to the enclosure 300 of FIGS. 5-7 can be incorporated into the enclosures described above and can be utilized in a data storage system such as the data storage system 100 of FIG. 1.

For purposes of explanation, the internal space of the enclosure 300 has been split into four areas (A, B, C, and D), however, the enclosure 300 could include additional sections and air movers. An air mover 310 is positioned in each area, and each air mover 310 can include a set of blades that are rotated to move air within the enclosure 300. A temperature sensor 314 is also positioned in each area, and there are also temperature sensors 314 positioned outside the enclosure 300.

In the example of FIG. 5, each of the air movers 310 is operated (e.g., rotated) such that air passes from the left side of the enclosure 300 to the right side of the enclosure 300. For example, air first passes through areas A and C to respective areas B and D. The left side of the enclosure 300 can represent the front end of the enclosure, and the right side of the enclosure 300 can represent the band end of the enclosure 300. The air movers 310 on the left of the enclosure 300 are rotated such that they pull air from outside of the enclosure 300 into the enclosure 300, and the air movers 310 on the right of the enclosure 300 are rotated such that they pull air from inside the enclosure 300 to the exterior of the enclosure 300. As a result, the air generally moves towards the right side of the enclosure 300, as represented by the four arrows.

In the air flow configuration of FIG. 5, cooling is most effective when the air on the left side of the enclosure 300 (or outside the left side of the enclosure 300) is cooler than the air on the right side of the enclosure 300. As such, the cooler air—rather than the hotter air—that is available for cooling flows through the enclosure 300 to cool components (e.g., electronic components such as integrated circuits and/or data storage devices) positioned in the enclosure 300.

To determine whether the air movers 310 are directing cooler air through the enclosure 300 along a desired path and/or to hot spots, temperature signals (e.g., electrical signals indicating a measured temperature) generated by the temperature sensors 314 can be analyzed by the central controller 304B (shown in FIGS. 3 and 4). The temperature signals—and other sensor signals—can be analyzed periodically (e.g., once a minute, once every five minutes, once every ten minutes).

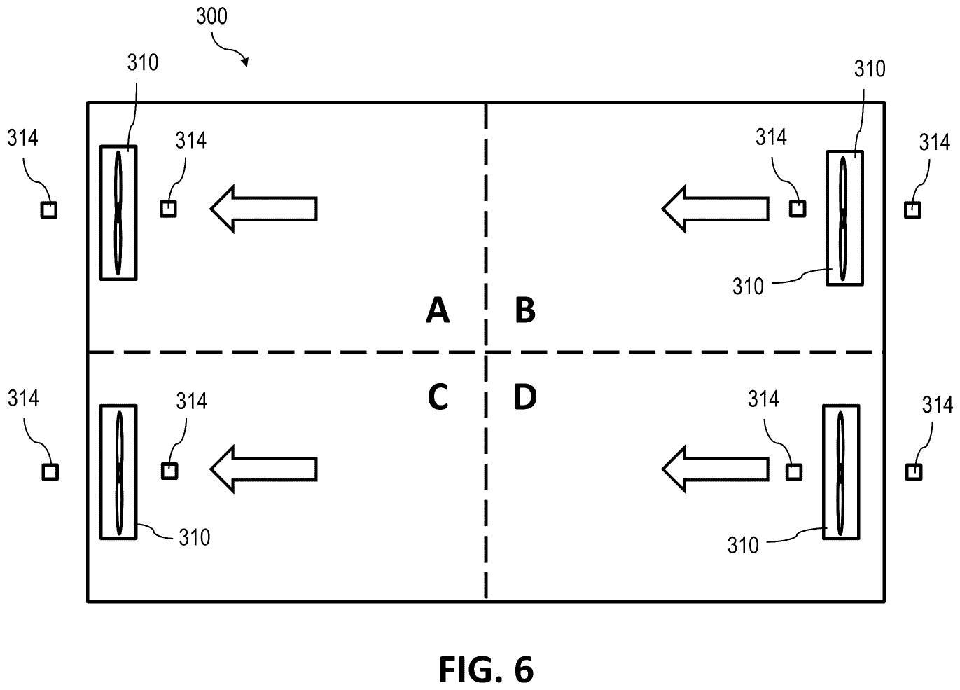

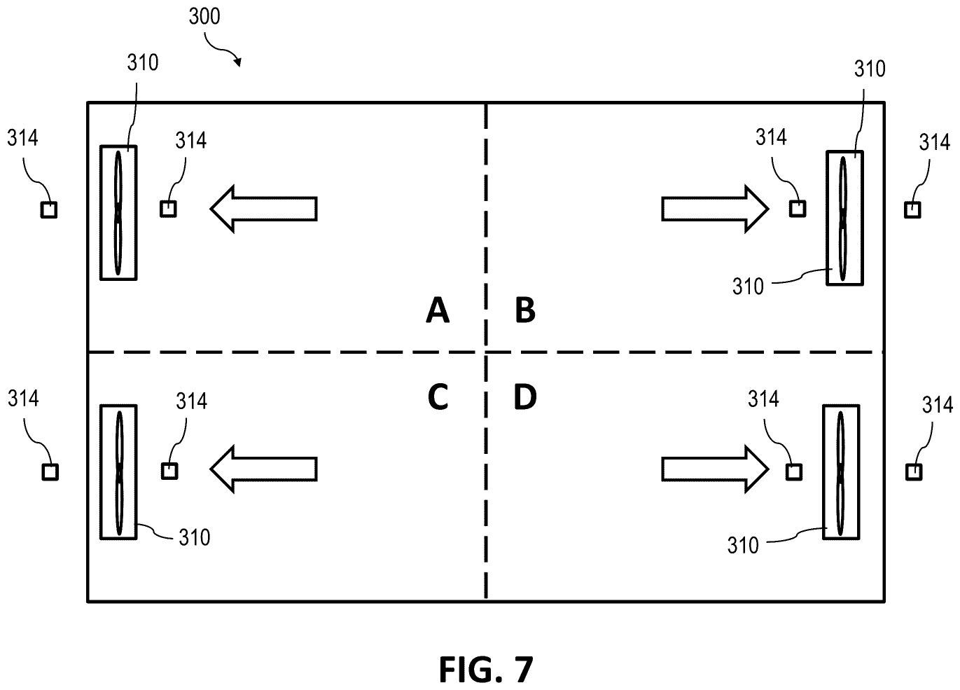

As one example, if the signals from the temperature signals generated by the temperature sensors 314 positioned outside the enclosure 300 indicate that the air on the left side of the enclosure 300 is a lower temperature than the air on the right side of the enclosure 300, then the central controller 304B can continue to maintain how the air movers 310 are operating. In certain embodiments, the temperature sensors 314 positioned external to the enclosure 300 are located far enough away (e.g., two feet or more) from the enclosure 300 such that the hot air exiting the enclosure 300 has a reduced effect on the measured air temperature. As discussed below in connection with FIGS. 6 and 7, if the sensed air temperatures indicate that another operating mode should be used, the central controller 304B can alter how the air movers 310 are operating.

As another example, if the temperature signals generated by the temperature sensors 314 indicate that one particular area of the enclosure 300 has a high air temperature, the central controller 304B can alter how one or more of the air movers 310 operate. For a more specific example, if the temperature signals indicate that one of the areas (e.g., Area B) has a temperature higher than a set threshold, the air mover 310 positioned in Area B and/or the air mover 310 positioned in Area A can be controlled such that their rotation speed increases. The increased speed causes a higher volume of air to pass through Area B during a given period of time. In certain embodiments, the air movers 310 are configured to operate at different speeds (e.g., 5,000-15,000 rpm). As such, the air mover 310 may initially be operated at 5,000 rpm and then increased 2- or 3-times the normal operating speed (e.g., up to 15,000 rpm).

In certain embodiments, the central controller 304B increases the rotation speed of the relevant air movers 310 until the relevant flow sensors 316 detect a threshold flow rate. In other embodiments, the increase in rotation speed is a predetermined speed. In other embodiments, the central controller 304B increases the rotation speed of the relevant air movers 310 until a certain acoustic energy (e.g., noise as measured in decibels) is detected. Increased rotation of the blades causes increased acoustic energy generated by the air movers 310, which can negatively affect the performance of the data storage devices positioned within the enclosure 300.

Regardless of how the rotation speed is selected, the increased rotation speed can continue until the relevant measured temperatures fall beneath the set threshold. In certain embodiments, the threshold is set based on the maximum or upper range of operating temperatures of electronic components positioned within the area. As such, the threshold may vary from area-to-area.

FIG. 6 shows an example of when the air movers 310 are operated so that air is directed generally in an opposite direction than the example of FIG. 5. In this example, the central controller 304B has determined that cooling is more effective when the air on the right side of the enclosure 300 is cooler than the air on the left side of the enclosure 300. As a result, the central controller 304B can cause the blades of the air movers 310 to rotate in an opposite direction so that the air movers push air rather than pull air, or vice versa. In certain embodiments, this means that the blades are caused to rotate clockwise instead of counterclockwise, or vice versa. As such, the air movers 310 are designed to be able to rotate their blades in both clockwise and counterclockwise directions around a rotational axis, as directed by the central controller 304B in response to one or more sensor signals.

FIG. 7 shows an example where some of the air movers 310 are operated to rotate in one direction while other air movers 310 are operated in an opposite direction. In the example of FIG. 7, each of the air movers 310 is operated such that they each push air out of the enclosure 300.

As the air movers 310 are caused to change their rotational direction during operation, the central controller 304B can follow a routine such that the change in direction is not abrupt and therefore reduces the risk of damaging the air movers 310. The remaining part of this paragraph describes an example where one or more of the air movers 310 are initially rotating their blades clockwise around their rotation axis. Once the central controller 304B determines that the rotational direction should be reversed, the central controller 304B begins to gradually reduce the rotational speed (e.g., by reducing the amount of power supplied to the air movers 310) of the blades until the blades stop rotating. In certain embodiments, the air movers 310 apply a brake to reduce their rotational speed more quickly. After the clockwise rotation stops (e.g., an rpm of zero), the central controller 304B can begin supplying power to the air movers 310 such that the blades begin to rotate in a counterclockwise direction. The central controller 304B can gradually increase the amount of power supplied to the air movers 310 until the air movers 310 reach their desired operating speed.

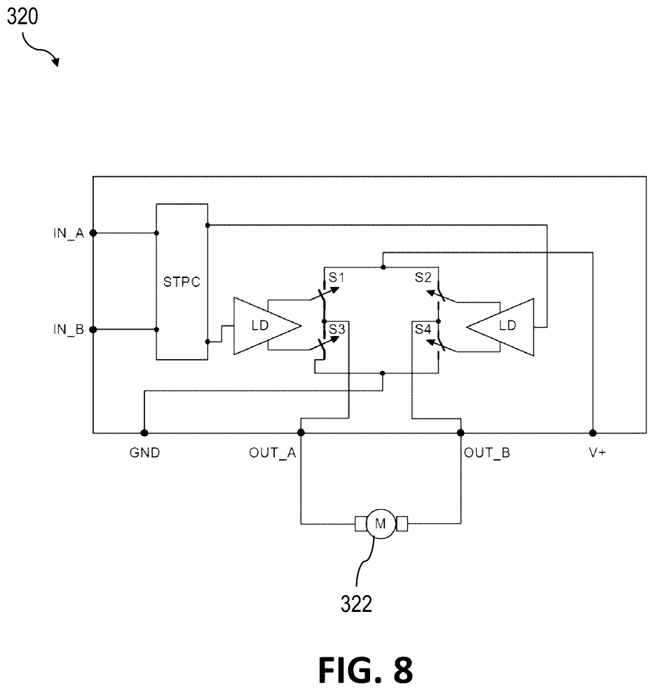

FIG. 8 shows an example circuit 320 for operating the air movers 310, although other circuit designs can be used. The circuit 320 ultimately controls the direction and speed of a motor 322 of the air movers 310. The circuit 320 has two inputs (IN_A and IN_B) that receive control signals from the central controller 304B. The desired speed is is achieved by pulse-width-modulating the input signals. The circuit 320 also includes a shoot-through protection circuit (STPC), line drivers (LDs), solid-state switches (S1, S2, S3, and S4) comprising the H-bridge, and outputs (OUT_A, OUT_B) which are operatively connected to the motor 322.

Below is an exemplary table that shows how the inputs affect the operating mode of the air movers 310 using the circuit 320.

| IN_A | IN_B | OUT_A | OUT_B | EFFECT |
|---|---|---|---|---|
| 0 | 0 | 0 | 0 | BRAKE |
| 0 | 1 | 0 | 1 | +DIR |
| 1 | 0 | 1 | 0 | −DIR |
| 1 | 1 | HiZ | HiZ | OPEN |

When both inputs are in a zero state, the circuit 320 causes the motor 322 to brake. When the first input (IN_A) is in a zero state and the second input (IN_B) is in a one state, the motor 322 rotates in a clockwise direction (+DIR). When the first input (IN_A) is in a one state and the second input (IN_B) is in a zero state, the motor 322 rotates in a counterclockwise direction (−DIR). And, when both inputs are in a one state (e.g., a high impedance (HiZ) state), the motor load is disconnected (OPEN). The circuit 320 as shown in FIG. 8 can be described as a buffered H-bridge circuit.

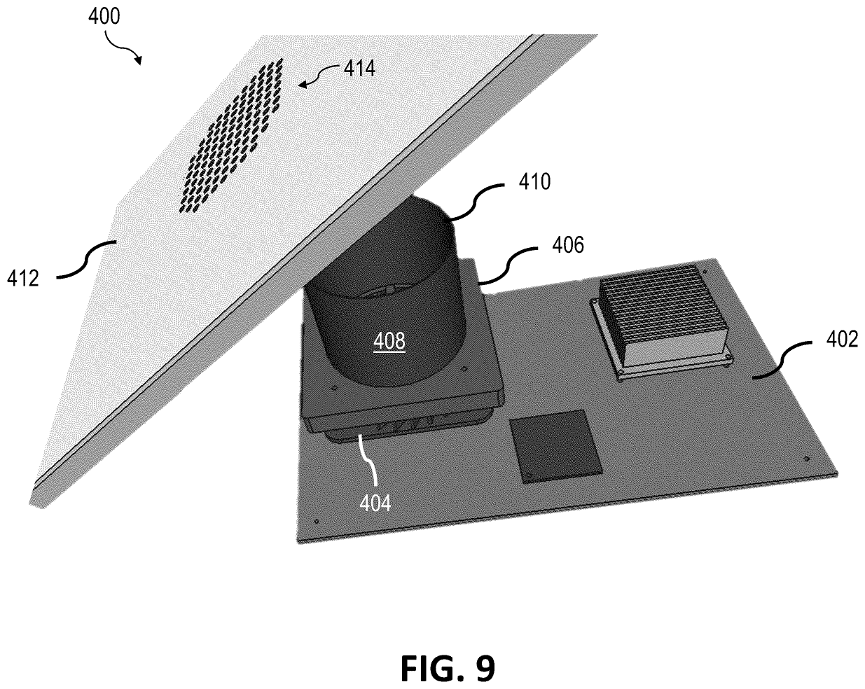

FIG. 9 shows another example enclosure 400. Like the other enclosures described herein, the enclosure 400 includes a printed circuit board 402 on which multiple electronic components 404 are electrically and mechanically coupled to. In the example of FIG. 9, one of the electronic components 404 is coupled to an air mover 406. In certain embodiments, as previously shown in FIG. 3, a heat sink can be positioned between the electronic component 404 and the air mover 406. Further, a thermal interface material can be positioned between the electronic component 404 and the heat sink.

FIG. 9 shows a heat chimney 408 coupled to (e.g., directly mechanically coupled to) the air mover 406. The heat chimney 408 can include one or more walls 410 that create a hollow interior space to permit air to flow through. For example, the heat chimney 408 can be cylinder-shaped such that the heat chimney 410 forms a pipe-like structure. One end of the heat chimney 408 can be coupled to the air mover 406 and the other end can be coupled to a wall or cover 412 of the enclosure 400. As such, the heat chimney 408 can extend between the air mover 406 and the cover 412 of the enclosure 400. The cover 412 of the enclosure 400 can includes openings 414 that allow air to pass through into or out of the heat chimney 408.

During operation of the electronic component 404, the air mover 406 can rotate such that air is directed towards or away from the electronic component 404 to cool the electronic component 404 as needed. The heat chimney 408 is arranged and shaped to isolate air passing between an exterior of the enclosure 400 and the air mover 406. For example, the air entering the heat chimney 408 from the exterior of the enclosure 400 can pass through the heat chimney without being disturbed by—or otherwise mixed with—air passing within the enclosure 400 outside the heat chimney 408. As such, heat generated by the electronic component 404 can be directed out of the enclosure 400 with having little effect on the temperature of the air outside of the heat chimney 408 and passing through the enclosure 400. In certain embodiments, the heat chimney 408 comprises a material with a low thermal conductivity such as a plastic rather than a metallic material. In certain embodiments, the heat chimney 408 is coupled to (e.g., fluidly and mechanically coupled to (directly or indirectly)) to the electronic component 404 that generates the most heat or that consumes the most power relative to the other electronic components in the enclosure 400. In certain embodiments, multiple heat chimneys are used in the enclosure 400.

In certain embodiments, like the air movers described above, the air mover 406 coupled to the heat chimney 408 can be controlled to rotate in a clockwise or counterclockwise direction depending on measured temperatures. For example, given measured temperatures, it may be more useful to pull air from outside of the enclosure 400 through the heat chimney 408 and towards the electronic component 404 to cool the electronic component 404, or vice versa.

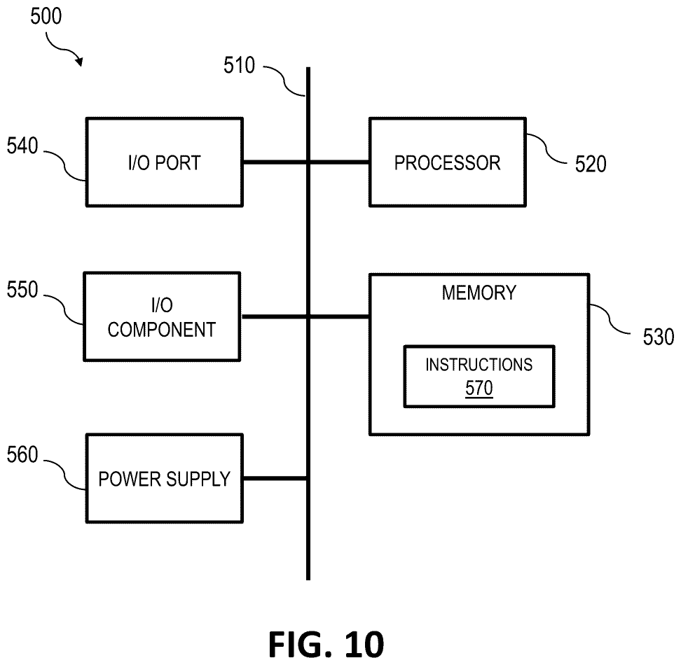

FIG. 10 is a block diagram depicting an illustrative computing device 500, in accordance with instances of the disclosure. The computing device 500 may include any type of computing device suitable for implementing aspects of instances of the disclosed subject matter. Examples of computing devices include specialized computing devices or general-purpose computing devices such as workstations, servers, laptops, desktops, tablet computers, hand-held devices, smartphones, general-purpose graphics processing units (GPGPUs), and the like. Each of the various components shown and described in the Figures can contain their own dedicated set of computing device components shown in FIG. 10 and described below.

In instances, the computing device 500 includes a bus 510 that, directly and/or indirectly, couples one or more of the following devices: a processor 520, a memory 530, an input/output (I/O) port 540, an I/O component 550, and a power supply 560. Any number of additional components, different components, and/or combinations of components may also be included in the computing device 500.

The bus 510 represents what may be one or more busses (such as, for example, an address bus, data bus, or combination thereof). Similarly, in instances, the computing device 500 may include a number of processors 520, a number of memory components 530, a number of I/O ports 540, a number of I/O components 550, and/or a number of power supplies 560. Additionally, any number of these components, or combinations thereof, may be distributed and/or duplicated across a number of computing devices.

In instances, the memory 530 includes computer-readable media in the form of volatile and/or nonvolatile memory and may be removable, nonremovable, or a combination thereof. Media examples include random access memory (RAM); read only memory (ROM); electronically erasable programmable read only memory (EEPROM); flash memory; optical or holographic media; magnetic cassettes, magnetic tape, magnetic disk storage or other magnetic storage devices; data transmissions; and/or any other medium that can be used to store information and can be accessed by a computing device. In instances, the memory 530 stores computer-executable instructions 570 for causing the processor 520 to implement aspects of instances of components discussed herein and/or to perform aspects of instances of methods and procedures discussed herein. The memory 530 can comprise a non-transitory computer readable medium storin the computer-executable instructions 570.

The computer-executable instructions 570 may include, for example, computer code, machine-useable instructions, and the like such as, for example, program components capable of being executed by one or more processors 520 (e.g., microprocessors) associated with the computing device 500. Program components may be programmed using any number of different programming environments, including various languages, development kits, frameworks, and/or the like. Some or all of the functionality contemplated herein may also, or alternatively, be implemented in hardware and/or firmware.

According to instances, for example, the instructions 570 may be configured to be executed by the processor 520 and, upon execution, to cause the processor 520 to perform certain processes. In certain instances, the processor 520, memory 530, and instructions 570 are part of a controller such as an application specific integrated circuit (ASIC), field-programmable gate array (FPGA), and/or the like. Such devices can be used to carry out the functions and steps described herein.

The I/O component 550 may include a presentation component configured to present information to a user such as, for example, a display device, a speaker, and/or the like, and/or an input component such as, for example, a wireless device, a keyboard, a touch input device, a touch-screen device, a mouse, and/or the like.

Aspects of the present disclosure are described with reference to flowchart illustrations and/or block diagrams of methods, devices, systems and computer program products. It will be understood that each block of the flowchart illustrations and/or block diagrams, and combinations of blocks in the flowchart illustrations and/or block diagrams, can be implemented by computer program instructions.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

We claim:

1. A data storage system comprising:
an enclosure;
a printed circuit board positioned in the enclosure;
an integrated circuit mechanically and electrically coupled to the printed circuit board;
temperature sensors configured to generate temperature signals in response to measured temperatures;
an air mover coupled to the enclosure and including a motor rotatable in a clockwise direction and a counterclockwise direction; and
a controller configured to cause rotation of the motor in either the clockwise direction or the counterclockwise direction depending on the temperature signals.

2. The data storage system of claim 1, further comprising a heat sink positioned between the air mover and the electronic component, wherein the heat sink is coupled to the electronic component.

3. The data storage system of claim 2, wherein the air mover is directly coupled to the heat sink.

4. The data storage system of claim 2, further comprising a thermal interface material directly coupled to the heat sink and the electronic component.

5. The data storage system of claim 1, further comprising:
a chimney positioned between the air mover and a wall of the enclosure.

6. The data storage system of claim 5, wherein the chimney is arranged and shaped to isolate air passing between an exterior of the enclosure and the air mover.

7. The data storage system of claim 5, wherein the chimney comprises a hollow cylinder.

8. The data storage system of claim 1, wherein some of the temperature sensors are positioned within the enclosure.

9. The data storage system of claim 1, wherein some of the other temperature sensors are positioned outside the enclosure.

10. The data storage system of claim 1, wherein the motor is configured to operate at multiple speeds.

11. The data storage system of claim 10, wherein the controller is further configured to cause rotation of the motor at a first speed or a second different speed depending on the temperature signals.

12. The data storage system of claim 1, further comprising a flow sensor positioned within the enclosure to detect air flow rates.

13. The data storage system of claim 12, wherein the controller is further configured to cause rotation of the motor depending on the air flow rates detected by the flow sensor.

14. The data storage system of claim 1, further comprising an H-bridge circuit electrically coupled between the controller and the air mover.

15. The data storage system of claim 1, wherein the temperature sensors are electrically coupled to the printed circuit board.

16. A method for controlling rotation directions of a motor of an air mover, the method comprising:
measuring, using multiple temperature sensors, temperature of air at different locations within a data storage enclosure;
rotating the motor of the air mover in a clockwise direction; and
changing a rotation direction of the motor to a counterclockwise direction depending on the temperature of air measured at the different locations.

17. The method of claim 16, further comprising:
increasing a rotation speed of the motor depending on the temperature signals.

18. The method of claim 16, wherein the changing the rotation direction comprises:
receiving control signals by an H-bridge circuit from a central controller, wherein the H-bridge circuit causes the changing the rotation direction.

19. The method of claim 16, further comprising:
measuring temperature of air at different locations outside the data storage enclosure, wherein the changing the rotation direction further depends on the temperature of air at the different locations outside the data storage enclosure.

20. A system comprising:
a controller configured to generate control signals in response to temperature signals representative of air temperatures at multiple locations within a data storage enclosure; and
an integrated circuit electrically coupled to the controller and configured to drive a motor of an air mover in a first direction, then brake, and then rotate in a second direction that is opposite to the first direction.
